(19) United States
(12) Patent Application Publication
(10) Pub. No.: US 2026/0135509 A1
(43) Pub. Date: May 14, 2026

(54) PREDICTIVE POWER MANAGEMENT FOR MODULAR ENERGY PLATFORMS WITH RENEWABLE-FIRST OPERATION

(71) Applicant: Stealth Power, LLC, Austin, TX (US)

(72) Inventors: Maclain P. Lodell, Austin, TX (US); D. Shannon Sentell, JR., Austin, TX (US); Irfan Ali, Pflugerville, TX (US)

(21) Appl. No.: 19/388,955

(22) Filed: Nov. 13, 2025

Related U.S. Application Data
(60) Provisional application No. 63/720,173, filed on Nov. 13, 2024.

(51) Int. Cl. H02S 10/40; G01R 31/382; G01R 31/392; G06Q 50/06; H02J 3/00; H02J 3/38; H02J 13/00; H02S 10/20; H02S 20/32; H02S 40/42

(52) U.S. Cl. CPC H02S 10/40; G01R 31/382; G01R 31/392; G06Q 50/06; H02J 3/0012; H02J 3/003; H02J 3/004; H02J 3/381; H02J 13/12; H02J 13/1333; H02J 13/333; H02S 10/20; H02S 20/32; H02S 40/42; H02J 2101/25; H02J 2103/30; H02J 2105/52; H02J 2105/55

(57) ABSTRACT

A smart charging system for modular power platforms is configured to supply electrical power at a point of use. A power source, including one or more renewable energy devices, supplies electrical energy to an energy storage system characterized by a state of charge. An external power interface receives power from an external power network such as a grid or generator. A smart charging control box, implemented by at least one processor and non-transitory memory, monitors the state of charge, predicts future energy-storage conditions based on historical load information and energy-generation information for the first power source, and selectively allows or blocks power intake from the external power network so as to preferentially utilize renewable energy while maintaining policy-declared operating limits. In some embodiments, an auxiliary control box and fleet-level control logic further manage power export from a hub platform to additional platforms, enabling coordinated, deterministic power distribution across a fleet.

### CROSS-REFERENCE TO RELATED APPLICATION

This application claims the benefit of U.S. provisional application No. 63/720,173, filed Mar. 9, 2024, entitled “SMART CHARGING SYSTEM FOR SOLAR-POWERED TRAILERS WITH OPTIMIZED BATTERY MANAGEMENT AND PREDICTIVE CONTROL”, and which is incorporated herein by reference in its entirety.

### FIELD OF THE DISCLOSURE

The present application relates generally to the field of renewable and hybrid energy management systems, and more specifically to solar energy management systems involving power management, battery charging, and hybrid energy systems.

### BACKGROUND OF THE DISCLOSURE

Modular power platforms are systems that integrate one or more local energy sources with an energy storage system to provide electrical power at or near a point of use. In many implementations, these platforms are configured as mobile or semi-portable units (such as trailers, skid-mounted systems, or containerized power modules) equipped with renewable energy devices that convert ambient energy (for example, solar, wind, or geothermal) into electrical energy that is stored in onboard batteries or other storage technologies. These platforms can serve as portable and renewable power sources in locations where conventional grid electricity is limited, intermittent, or available only through an auxiliary or shoreline connection to an external power network. Typical deployment sites include construction areas, film sets, outdoor events, and other temporary or remote locations where local loads such as lighting, tools, communications equipment, and instrumentation must be powered.

One widely deployed class of modular power platforms is the solar-powered trailer. A solar-powered trailer is a mobile unit that mounts solar panels on a towable frame and uses onboard batteries to store the collected solar energy. Such trailers offer an attractive way to provide off-grid power using a renewable resource, and are frequently used in applications where mobility, rapid deployment, and reduced fuel consumption are valued. In practice, the trailer's power system often operates in hybrid fashion, combining solar input with one or more auxiliary power sources such as a shoreline grid connection or a generator. Similar hybrid configurations may be implemented in non-trailer modular platforms, such as ground-mounted skids or containerized units, which use solar arrays, small wind turbines, or other renewable devices together with batteries and an external power interface.

Since modular power platforms can be deployed wherever needed, they have found use in disaster relief and emergency response operations. In such scenarios, the platforms may provide immediate and flexible power for critical loads including medical equipment, refrigeration for medicines and vaccines, communication systems, and temporary shelters. Their ability to operate independently of existing grid infrastructure makes them especially useful in locations where utility service is damaged, overloaded, or unavailable. In military and defense contexts, modular power platforms and solar-powered trailers may support field operations by powering command posts, communications gear, and surveillance systems, offering a quieter and logistically simpler alternative to diesel-only generator sets.

Recreational users, such as campers and outdoor enthusiasts, also utilize modular power platforms and solar-equipped trailers. In these contexts, the platforms provide an environmentally friendly way to power appliances, charge devices, and run small tools while off-grid, enhancing comfort and convenience without relying solely on fuel-burning generators. In environmental monitoring, scientific research, and industrial sensing applications, modular power platforms can supply electricity for wildlife tracking, weather monitoring, geophysical surveys, and other instruments in remote or environmentally sensitive areas, helping reduce the need for frequent site visits and minimizing local impact.

Modular power platforms and solar-powered trailers can also serve as mobile charging stations for electric vehicles in locations where permanent charging infrastructure is sparse or absent. By combining one or more renewable energy sources with onboard storage and an external power interface, such platforms can operate either as stand-alone systems or as hybrid nodes that supplement or are supplemented by conventional grid or generator power. This versatility supports a wide range of use cases, from temporary event power and pop-up EV charging to longer-term deployments in off-grid communities or developing infrastructure corridors.

### BRIEF DESCRIPTION OF THE DRAWINGS

FIG. 1 is an illustration of a solar trailer.

FIG. 2 is a high level view of a mobile power system in accordance with the teachings herein.

FIG. 3 is an illustration of control box hardware in accordance with the teachings herein.

FIG. 4 is a photograph of an embodiment of the control box of FIG. 3.

FIG. 5 is an illustration of the software hierarchy of the control algorithm.

FIGS. 6-7 are illustrations of a second embodiment which is designed to optimize power distribution across multiple connected trailers.

FIG. 8 is a top-down view of an exemplary bi-directional power module showing an enclosure, high-current relays, conductors, and external connectors suitable for use as a shoreline and export interface in the disclosed modular power platform.

FIG. 9 is a schematic diagram of the bi-directional power module of FIG. 8, illustrating AC power paths, relay contacts, current-sensing elements, and a low-voltage supply used to drive relay coils and status indicators.

FIG. 10 is a functional block diagram of a two-relay bi-directional power configuration showing connections between an inverter output, inverter input, and an external power connector, together with relay-controlled input, output, and bypass modes.

FIG. 11 is a control-plane block diagram illustrating integration of the bi-directional power module with a smart charging control box, including a microcontroller, relay drivers, sensor inputs, and status indicators used to implement the disclosed power-orchestration logic.

FIG. 12 is a state diagram and associated relay-state table for the two-relay bi-directional power configuration of FIG. 10, defining input, output, and bypass operating modes as functions of relay states.

### SUMMARY OF THE DISCLOSURE

In one aspect, a smart charging system is provided for a modular power platform configured to supply electrical power at a point of use. The system comprises a first power source configured to supply electrical energy to the modular power platform, the first power source preferably comprising at least one renewable energy device; an energy storage system configured to store the electrical energy supplied by the first power source and characterized by a state of charge; an external power interface configured to receive electrical power from a power network external to the modular power platform; and a smart charging control box operatively connected to the energy storage system and the external power interface. One or more processors associated with the smart charging control box are configured to monitor a current state of charge of the energy storage system, predict future energy-storage conditions based at least on historical load information and energy-generation information for the first power source, and selectively allow or block power intake from the external power interface based on the predicted energy-storage conditions so as to preferentially utilize the first power source while maintaining the energy storage system within policy-declared operating limits. In certain embodiments, the modular power platform is implemented as a solar-powered trailer and the external power interface is a shoreline power connection.

In another aspect, a method of managing power intake for a modular power platform configured to supply electrical power at a point of use is provided. The method comprises monitoring a state of charge of an energy storage system configured to store electrical energy supplied by a first power source; predicting future energy-storage conditions of the energy storage system based at least on historical load information and energy-generation information for the first power source; and selectively enabling or disabling power intake from a power network external to the modular power platform via an external power interface based on the predicted energy-storage conditions so as to preferentially utilize the first power source while maintaining the energy storage system within predetermined operating limits. In certain implementations, the first power source comprises at least one renewable energy device selected from solar, wind and geothermal systems and the external power network comprises a shoreline connection to an electrical grid or a generator.

In a further aspect, a power distribution system is provided for a first modular power platform that operates in conjunction with at least one additional modular power platform. The system comprises a first power source configured to generate electrical energy for the first modular power platform; an energy storage system on the first modular power platform configured to store the electrical energy generated by the first power source and characterized by a state of charge; an external power interface configured to receive electrical power for the first modular power platform from a power network external to the modular power platforms; a smart charging control box operatively connected to the energy storage system and the external power interface; an auxiliary control box configured to transfer power from the energy storage system of the first modular power platform to at least one additional modular power platform; and at least one processor and non-transitory memory storing instructions which, when executed, configure the system to monitor the state of charge, predict future energy-storage conditions, enable or inhibit power intake from the external power interface based on a policy-declared input threshold, and enable power transfer to the at least one additional modular power platform when a policy-declared export threshold is satisfied.

In still another aspect, a smart charging system is provided for a first modular power platform that operates in conjunction with a set of additional modular power platforms. The system comprises a first power source configured to charge an energy storage system on the first modular power platform, the energy storage system being characterized by a state of charge; a power-distribution interface configured to transfer power from the energy storage system to at least one of the additional modular power platforms; and a smart charging control box operatively connected to the energy storage system and the power-distribution interface. One or more processors associated with the smart charging control box are configured to monitor the state of charge of the energy storage system, predict future energy-storage conditions based at least on historical load and energy-generation data, and selectively allow or block power transfer through the power-distribution interface to the at least one additional modular power platform based on the monitored state of charge and a predictive analysis of power needs for the first modular power platform and the additional modular power platforms.

In yet another aspect, a method is provided for managing power distribution in a system of modular power platforms equipped with respective energy storage systems. The method comprises monitoring a state of charge of an energy storage system of a first modular power platform; predicting, for a future time interval, an energy-storage condition of the energy storage system based at least on historical load data and energy-generation data for a first power source associated with the first modular power platform; and selectively enabling power transfer from the energy storage system of the first modular power platform to one or more additional modular power platforms only when the predicted energy-storage condition indicates that the state of charge will remain above a policy-declared reserve threshold for the future time interval. In some embodiments, the modular power platforms are implemented as solar-powered trailers that share power among themselves while selectively drawing from an external power network on an as-needed basis.

### DETAILED DESCRIPTION

While solar-powered trailers and related modular power platforms offer several advantages, they also suffer from a number of infirmities. For example, conventional systems that combine a local renewable source with an external grid or generator can face significant challenges in optimizing renewable energy use once the external power network is integrated. If such platforms are frequently connected to external power to prevent depletion of onboard storage, the renewable source (such as a solar array) may be underutilized, thereby reducing overall system efficiency. In many implementations this results in wasted renewable energy potential, as the energy storage system remains substantially maintained by the external power network, preventing the renewable source from operating at or near its maximum generation capability.

Moreover, existing systems often rely on manual management of the external power connection, requiring users to plug and unplug a shoreline connection or otherwise intervene to optimize charging and renewable energy utilization. This manual process is cumbersome and prone to human error (such as, for example, forgetting to disconnect the external power connection), thereby leading to potential overcharging, undercharging, or unnecessary reliance on non-renewable sources. Consequently, this reliance on manual control diminishes system reliability and hampers effective energy management for mobile and stationary modular platforms alike.

Furthermore, many solar trailer systems and other modular power platforms lack sophisticated predictive control capabilities configured to dynamically manage power inputs based on anticipated conditions. Instead, these systems typically rely on static rules or fixed thresholds, rather than leveraging real-time data analytics to forecast energy needs and renewable-generation capacity. As a result, management of energy flow may be suboptimal, which can cause unnecessary depletion of the energy storage system or overuse of power from the external network. Additionally, traditional energy management systems often do not effectively adapt to varying weather conditions, historical energy-usage patterns, or future energy demand, further reducing the effectiveness of the charging system in maximizing use of renewable energy.

It has been found that some or all of the foregoing problems may be addressed with the systems and methodologies disclosed herein. In preferred embodiments, the limitations of existing solar-powered trailer systems and other modular power platforms are addressed by introducing a power platform having a smart charging control box equipped with a predictive control engine. The smart charging control box monitors the state of charge of an energy storage system (such as a battery or battery array) and predicts future energy-storage conditions, enabling it to selectively allow or block intake of power from an external power network based on anticipated needs. As a result, the energy storage system is charged primarily through a first power source whenever possible, thereby improving or maximizing use of renewable energy and minimizing reliance on non-renewable or externally sourced power. This approach addresses the inefficiencies associated with underutilized renewable generation in conventional systems.

Additionally, preferred embodiments of the systems and methodologies disclosed herein automate management of an external power interface, thereby reducing or eliminating the need for manual plugging and unplugging of external power connections. By continuously monitoring energy-storage conditions and automatically enabling or disabling power intake from the external power network as required, the smart charging control box may significantly enhance reliability and reduce the risk of human error. This approach not only streamlines the charging process but also provides a more efficient and user-friendly experience for operators of both mobile and stationary power platforms.

Preferred embodiments of the systems and methodologies disclosed herein further incorporate a predictive control algorithm that uses historical load data and forecasts for renewable generation (for example, solar irradiance forecasts) to predict energy-storage conditions and energy demand over a fixed time interval, preferably the next 24 hours. This advanced predictive capability allows the system to make informed, data-driven decisions about when to permit power intake from the external power network, optimizing energy management and helping to prevent unnecessary depletion of the energy storage system or over-reliance on grid or generator power. This feature directly addresses the absence or limited use of predictive control in many conventional solar-powered trailers and other modular power platforms.

Moreover, preferred embodiments of the systems and methodologies disclosed herein are designed to be adaptive to changing conditions by integrating both real-time and historical data. The control algorithm dynamically adjusts system parameters to maintain the energy storage system within policy-declared operating limits that promote a favorable state of charge, thereby enabling increased capture of renewable energy. This adaptability allows the modular power platform to operate efficiently under a variety of environmental and load conditions, making it more robust and effective compared to traditional static energy management systems.

It will be appreciated from the foregoing that preferred embodiments of the systems and methodologies disclosed herein comprise a modular power platform and a smart charging control box which are connected via power and communication links. These components interact to optimize power intake and maximize use of energy from the first power source. A communications link serves as a communication path that enables the smart charging control box to monitor the state of charge (SOC) of the energy storage system, renewable generation rates, and energy-consumption patterns within the modular power platform or across a fleet of platforms. This continuous data exchange allows the control box to maintain real-time insights into the system's energy status, enabling it to make informed decisions regarding power management, including selective intake of power from an external power network and selective export of power to other connected platforms or loads.

The systems, devices, and methodologies disclosed herein may be further understood with respect to the following particular, non-limiting embodiments. While frequent reference is made to embodiments featuring trailer-based systems, it is to be understood that the teachings herein are more broadly applicable to systems involving modular power platforms (typically featuring one or more renewable power sources), external power networks, and the smart, predictive sourcing of power between them using a smart charging control box (150) and associated control logic.

As used herein, a policy snapshot refers to a configuration record, data structure, or other machine-readable representation specifying one or more power-management parameters for a modular power platform or a fleet of modular power platforms. A policy snapshot may include, without limitation, a forecast horizon, one or more reserve thresholds, one or more export thresholds, per-platform power-management constraints, priority classes, safety limits, and time-window parameters.

As used herein, a reserve threshold refers to a minimum state-of-charge (SOC) value or other energy-storage criterion that the system attempts to maintain in an energy storage system over a forecast interval. When predicted SOC falls below the reserve threshold, the control logic may enable power intake from an external power network.

As used herein, an export threshold refers to a state-of-charge value or other energy-storage criterion greater than the reserve threshold and indicative of surplus stored energy. When predicted SOC exceeds the export threshold, the control logic may enable export of power to additional modular power platforms or to other loads.

As used herein, a “modular power platform” means a power system implemented on a discrete physical platform that integrates at least a first power source, an energy storage system, and power-management electronics, and that is deployable as a unit at or near a point of use, such as on a trailer, skid, container, vehicle body, or fixed rack.

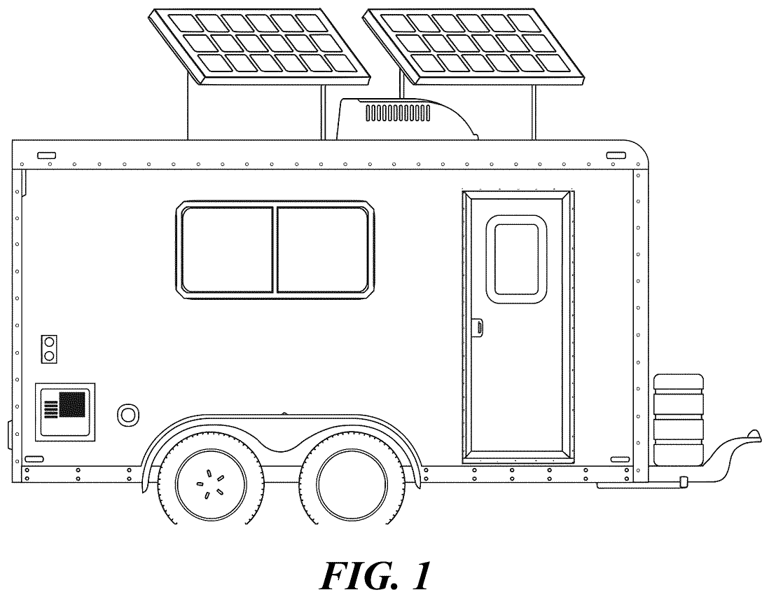

FIG. 1 depicts a particular, non-limiting embodiment of a solar-powered trailer (100) in accordance with the teachings herein. In this embodiment, the solar-powered trailer (100) is an example of a modular power platform implemented on a mobile frame (112) and designed to capture, store, and manage solar energy efficiently, thereby providing a reliable off-grid power source for various applications. The trailer (100) includes a first power source in the form of one or more solar panels (110) mounted on the roof or sides, which convert sunlight into direct current (DC) electricity. This electricity is provided to an energy storage system (120) comprising one or more onboard batteries (122), preferably deep-cycle types such as lithium-ion, allowing for power availability during periods without sunlight. An inverter (130) converts the stored DC power into alternating current (AC) power suitable for running appliances and equipment.

To regulate the charging process and protect the energy storage system (120), the trailer includes a charge controller (140). This component prevents overcharging and excessive discharge, helping to ensure longevity and safe operation of the batteries (122). In some embodiments, the charge controller (140) incorporates Maximum Power Point Tracking (MPPT) functionality (142) to optimize solar power conversion efficiency. Complementing these components is a power-management system integrated with the smart charging control box (150), which monitors and manages energy flows between the solar panels (110), the energy storage system (120), and any external power sources. This system may feature a display panel (152) for real-time monitoring of state of charge, power usage, and solar input, and may include predictive algorithms to optimize energy usage based on forecasts and historical data.

In certain embodiments, the solar-powered trailer (100) is equipped with an external power interface (160), such as a shoreline power input, that allows connection to an external power network, for example a utility grid or generator, thereby providing a backup or supplemental charging option. The mobile frame of the trailer (112) includes stabilizers and mounting systems for the solar panels and compartments for housing the energy storage system (120) and other equipment. The trailer may further include multiple AC and DC outlets (170), USB ports, and 12V sockets to support a variety of devices. Cooling and ventilation systems (172) are preferably integrated to prevent overheating of the batteries (122) and electronics.

The solar-powered trailers described herein may include various optional features (190). These may include foldable or expandable solar panels, LED lighting, water storage, satellite communication systems, and Wi-Fi hotspots. However, in preferred embodiments, such trailers combine a first power source (110), an energy storage system (120), an inverter (130), charge controller(s) (140, 142), and a smart power-management system implemented by the smart charging control box (150). The trailer may further include a communications link (180), such as wired or wireless cabling (182), to support system diagnostics, remote monitoring, and integration into fleet-oriented orchestration systems.

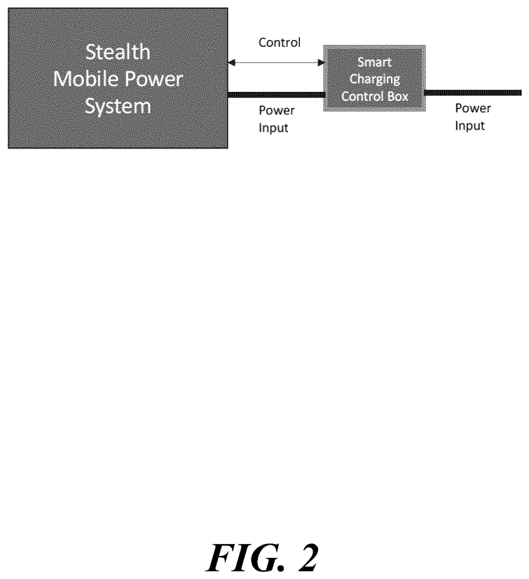

FIG. 2 is a schematic depiction of a smart charging system of the type disclosed herein. In the system depicted, the smart charging control box (150) employs a predictive control algorithm (210) executed by a processor or microcontroller (900). The algorithm (210) utilizes historical load data (220), real-time energy-generation information from the first power source (110), and weather-forecast inputs (230) to predict energy needs for a subsequent time interval. The time interval is preferably the next 24 hours, but in some embodiments may be another interval such as the next two days, the next three days, or the next week. The predictive control algorithm (210) produces a forecasted energy-storage condition for the energy storage system (120), including the state of charge of an onboard battery or battery pack (122).

Based on these predictions, the smart charging control box (150) can dynamically decide whether to allow or block power intake from an external power network via the external power interface (160). For example, when generation from the first power source (110) is expected to be high and the energy storage system (120) has adequate charge, the smart charging control box (150) may prioritize renewable energy by holding the external power interface (160) in a blocked state. Conversely, when energy generation is predicted to be low—or when anticipated load (240) is high—the external power interface (160) may be enabled to maintain sufficient charge within the energy storage system (120) and prevent depletion. This dynamic interaction forms a feedback loop (250) between the modular power platform and the smart charging control box (150), allowing the system to adapt to changing conditions such as weather fluctuations or unexpected increases in energy demand. This adaptability facilitates improved or optimal energy utilization while minimizing reliance on non-renewable or externally sourced power. By automating power-intake management through the predictive control algorithm (210), the system reduces the need for manual intervention, improving reliability and reducing the risk of human error. This coordinated approach results in a more efficient, responsive, and sustainable power system, achieving the goals of maximizing renewable-energy utilization and enhancing overall energy management.

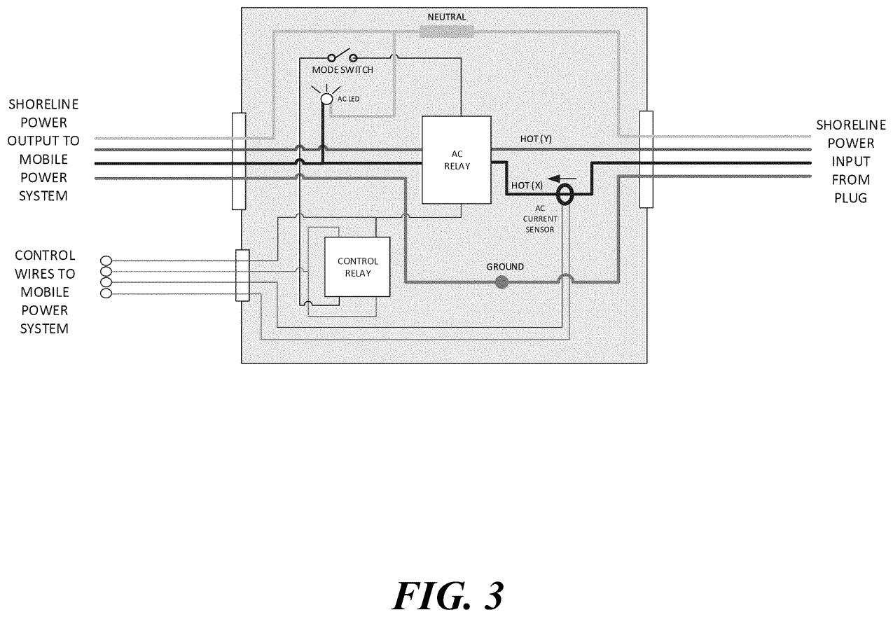

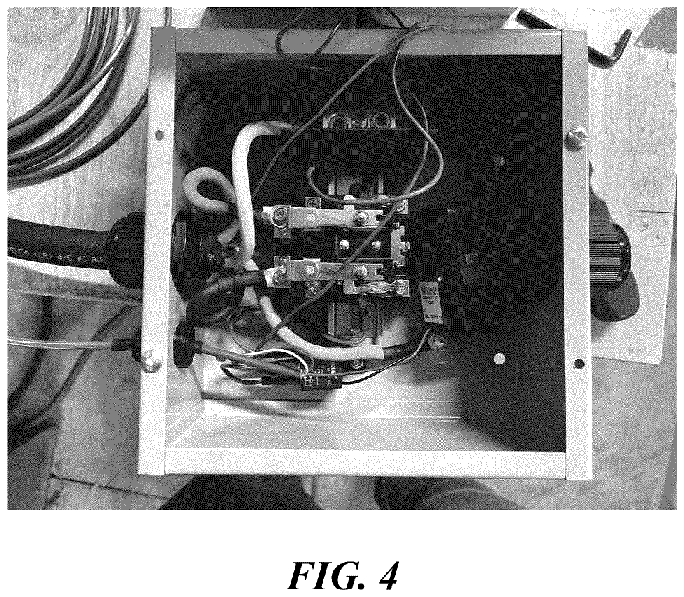

FIG. 3 depicts a particular, nonlimiting embodiment of control box hardware 300 of the type disclosed herein (FIG. 4 depicts an actual embodiment of such a control box). In this embodiment, the control box hardware 300 in a solar-powered trailer 100 (or other modular power platform) is a crucial component that manages the flow of power between the trailer's solar energy system and an external power source, such as shoreline power. The control box 150 is designed to automate power management, optimize energy usage, and enhance system reliability by preventing overcharging or unnecessary use of grid power. The interaction of its components, including a shoreline input 310, an AC relay 320, a control relay 330, user-input buttons 340, 342, an AC current sensor 350, and an enclosure 360, collectively achieves these goals.

The shoreline input 310 is the connection point where external AC power from an external power network (for example, a grid or a generator) is fed into the control box hardware 300. The shoreline input 310 allows the system to receive power when solar generation is insufficient or when the energy storage system 120 needs charging. The shoreline input 310 is therefore important for ensuring a continuous power supply under varying solar conditions.

The AC relay 320 is an electrically operated switch that controls the flow of AC power from the shoreline input 310 to the trailer's electrical system or to the energy storage system 120. The AC relay 320 is the primary mechanism that controls whether incoming shoreline power is passed through or blocked based on system requirements. The AC relay 320 operates in coordination with the control relay 330 to turn shoreline power on or off as needed.

The control relay 330 acts as an intermediary between control logic executed by the smart charging control box 150 and the AC relay 320. The control relay 330 receives relay control signals from control logic executed by a processor or microcontroller 900, indicating whether to activate or deactivate the AC relay 320. These signals are based on factors such as battery state of charge, predicted energy demand, and solar generation forecasts. By controlling the AC relay 320, the control relay 330 ensures that shoreline power is only used when necessary, optimizing the use of solar energy or other renewable inputs.

The “Solar Priority” (or “Auto”) button 340 and the “Shoreline Priority” (or “On”) button 342 on the control box hardware 300 provide manual overrides for a user. The “Auto” button 340 allows the control box 150 to operate under automated control based on algorithmic and predictive data. When pressed, the control box 150 will manage shoreline power based on predefined settings and real-time data. The “On” button 342, on the other hand, forces the AC relay 320 to connect shoreline power regardless of the automated settings, providing a manual option to ensure power availability in critical situations.

The AC current sensor 350 monitors the amount of current flowing through the shoreline input 310 when the AC relay 320 is activated. The AC current sensor 350 provides real-time data on power usage, which is useful for maintaining safe and efficient operation. This information is supplied back to the control logic in the smart charging control box 150 and helps the control algorithm make informed decisions about when to turn the AC relay 320 on or off, preventing overloads and contributing to optimal energy management.

The enclosure 360 houses the components of the control box hardware 300, protecting them from environmental factors such as dust, moisture, and physical damage. The enclosure 360 also serves as a safety feature, ensuring that electrical components are securely contained and reducing the risk of accidental contact or short circuits.

The components of the control box hardware 300 work together in a coordinated manner to manage power flow efficiently. When the system is set to “Auto” mode via the button 340, the control algorithm executed by the smart charging control box 150 constantly assesses the state of the energy storage system 120, solar input from the first power source 110, and the power needs of the trailer 100 or other modular power platform. Based on this data, the control logic sends a signal to the control relay 330, which deactivates or activates the AC relay 320 to either allow or block shoreline power through the shoreline input 310. If the system predicts that solar power is sufficient, the AC relay 320 remains off, conserving energy and reducing grid dependency. If the energy storage system 120 is low and solar generation is inadequate, the AC relay 320 is activated and shoreline power flows into the system.

Meanwhile, the AC current sensor 350 continuously monitors the power drawn from the shoreline input 310 and feeds this information back to the control algorithm within the smart charging control box 150. This closed-loop feedback mechanism allows the system to adapt dynamically to changing conditions, optimizing energy usage and helping to ensure reliable operation. The “Shoreline Priority” or “On” button 342 serves as a manual override, providing flexibility to ensure power availability when needed, while the “Solar Priority” or “Auto” button 340 reverts control back to the automated system.

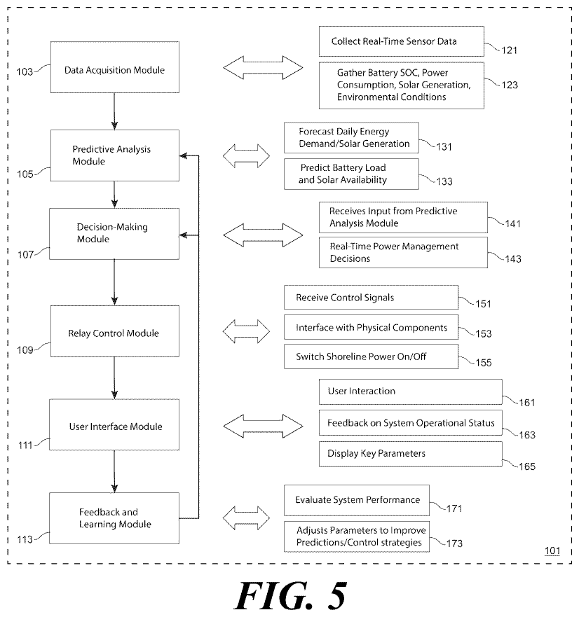

FIG. 5 is an illustration of a preferred embodiment of the software hierarchy of the control algorithm 501 utilized in the systems and methodologies disclosed herein. The primary objective of the control algorithm 501 is to optimize power input by managing the use of solar energy and shoreline (grid) power. It continuously monitors the state of charge (SOC) of the battery or energy storage system 120, predicts future energy demands and solar generation, and selectively controls shoreline power input via the external power interface 160 to ensure efficient energy use. The software may be embedded in a microcontroller or a microprocessor-based system 900 within the smart charging control box 150, interfacing with sensors, relays, and user-input components.

In a preferred embodiment, the software includes a data acquisition module 503, a predictive analysis module 505, a decision-making module 507, a relay control module 509, a user interface module 511, and a feedback and learning module 513. These functional modules interact to achieve the desired energy-management goals of the control algorithm 501.

The Data Acquisition Module 503 collects real-time data from various sensors, including AC current from the shoreline via the external power interface 160, the SOC of the energy storage system 120, solar-generation rate from the first power source 110, and environmental data (such as temperature and sunlight intensity). It also stores historical energy-consumption and generation data for predictive analysis.

The Predictive Analysis Module 505 uses historical data, real-time inputs, and machine-learning models or statistical methods to predict solar generation and energy consumption for a subsequent period of time, preferably the next 24 hours. Techniques such as time-series forecasting, regression analysis, or neural networks may be employed to enhance prediction accuracy based on weather forecasts, historical usage patterns, and other relevant factors.

Based on the predictive analysis and current system state, the Decision-Making Module 507 determines whether to allow or block shoreline power input. It applies predefined rules and thresholds to assess conditions where solar energy is sufficient to meet demand or when external power is required to protect against depletion of the energy storage system 120. The decision-making logic may use algorithms such as fuzzy logic, rule-based systems, or decision trees to provide flexibility and adaptability.

The Relay Control Module 509 directly interfaces with hardware components, including the control relay and AC relay, to execute decisions made by the Decision-Making Module 507. It sends control signals to the relays, enabling or disabling shoreline power input based on system need. The relay control signals may be communicated via a GPIO interface or other suitable hardware protocol.

The User Interface Module 511 handles user interactions via the “Auto” and “On” buttons or via a web-based dashboard. In “Auto” mode, the system operates according to automated control governed by the control algorithm 501. When the “On” button is pressed, this module overrides automated control to force shoreline power input through the external power interface 160, ensuring power availability in critical situations. Feedback may be provided through LEDs or a touchscreen display, indicating operational mode and key system parameters.

The Feedback and Learning Module 513 uses real-time data to continuously evaluate system performance and adjust the predictive models and decision-making rules to improve future accuracy and energy-management strategies. For example, if the system consistently underestimates energy consumption, the module 513 may automatically recalibrate prediction parameters.

It will be appreciated from the foregoing that the software for the smart charging system in a solar-powered trailer 100 or other modular power platform is composed of several interacting modules, each contributing a specific function toward optimizing energy input and maximizing renewable-energy usage. These modules work together to manage energy flow between renewable and external sources while minimizing manual intervention and improving reliability.

In use, the Data Acquisition Module 503 serves as the foundation for the system by collecting real-time data 521 from sensors such as AC current sensors, voltage sensors, and environmental sensors 523. It gathers information on SOC, power consumption, solar-generation rates, and environmental conditions 523 such as sunlight intensity and temperature. This real-time data, together with historical energy-usage patterns, is fed into the Predictive Analysis Module 505.

The Predictive Analysis Module 505 utilizes data from the Data Acquisition Module 503 to forecast energy demand and solar generation 531 for a future period, preferably the next 24 hours. Using machine-learning or statistical models, this module predicts battery load and solar availability 533 based on weather forecasts, historical trends, and real-time conditions. These predictions are then supplied to the Decision-Making Module 507.

The Decision-Making Module 507 receives input 541 from the Predictive Analysis Module 505 and uses this information to make real-time decisions 543 regarding whether to enable or block shoreline power intake. By analyzing the predicted SOC, power demand, and solar generation, the module chooses the most energy-efficient action. The output from this module is transmitted as control signals to the Relay Control Module 509.

The Relay Control Module 509 receives the control signals from the Decision-Making Module 507 and interfaces with hardware relays to execute the commanded actions. It switches shoreline power on or off as required to maintain optimal operation, responding rapidly to fluctuations in energy demand or renewable-energy availability.

The User Interface Module 511 allows users to interact with the system, preferably via a web dashboard but also via onboard interfaces such as buttons, LEDs, or a touchscreen display. The module 511 conveys operational status, such as “Auto” mode or “Manual” mode, and displays key metrics such as SOC, power consumption, and solar input. Users may manually override the automated control logic when necessary.

The Feedback and Learning Module 513 continuously evaluates discrepancies between predicted and actual outcomes (including energy usage or solar generation) and adjusts prediction parameters accordingly. For example, if the system consistently underpredicts solar-generation availability, module 513 may update the predictive model to improve accuracy. This adaptive capability ensures that the control algorithm 501 becomes more effective over time.

It will be appreciated from the foregoing that the interaction between these modules forms a comprehensive, adaptive system that effectively manages energy input in solar-powered trailers 100 and other modular power platforms. Data Acquisition Module 503 provides raw data, Predictive Analysis Module 505 forecasts energy needs, and Decision-Making Module 507 determines the appropriate actions. These are executed by Relay Control Module 509, while User Interface Module 511 facilitates user interaction. Feedback and Learning Module 513 continually refines performance to optimize energy efficiency, system reliability, and renewable-energy utilization.

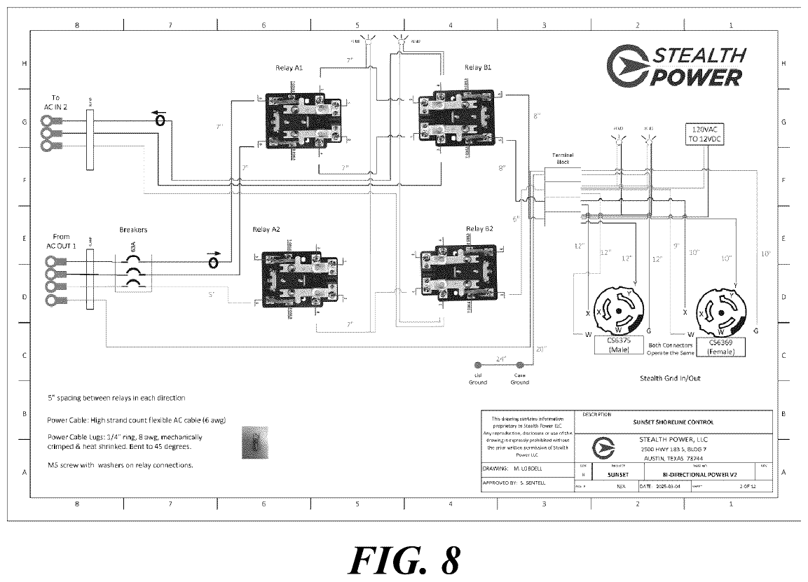

In certain embodiments, the smart charging and fleet-orchestration functionality described herein is implemented using a dedicated bi-directional power module (800) as illustrated in FIGS. 8-12. FIG. 8 shows a physical layout of a SUNSET BI-DIRECTIONAL POWER module disposed within an enclosure (802) sized to be mounted in or near a modular power platform such as a solar-powered trailer. The module (800) includes a set of high-current relays (804) mounted in spaced relation along a common mounting plane, with heavy-gauge, high-strand-count flexible AC conductors (806) routed between relay terminals (804a) and to front-panel connectors (808). In an illustrative configuration, the module provides a pair of high-current CS-style connectors (810) that serve as Stealth Grid In/Out interfaces, together with additional connectors (812) for coupling to the inverter output (814) and inverter input (816) of the platform's power electronics. The drawing further illustrates mechanical details such as conductor gauges (818), ring terminals (820), strain-relief structures (822), ground-bonding paths between the enclosure (802) and case lid (824), and indicative dimensions (826) between relay locations and mounting points, thereby providing a concrete mechanical embodiment for the bidirectional interface between the platform and an external AC source or sink

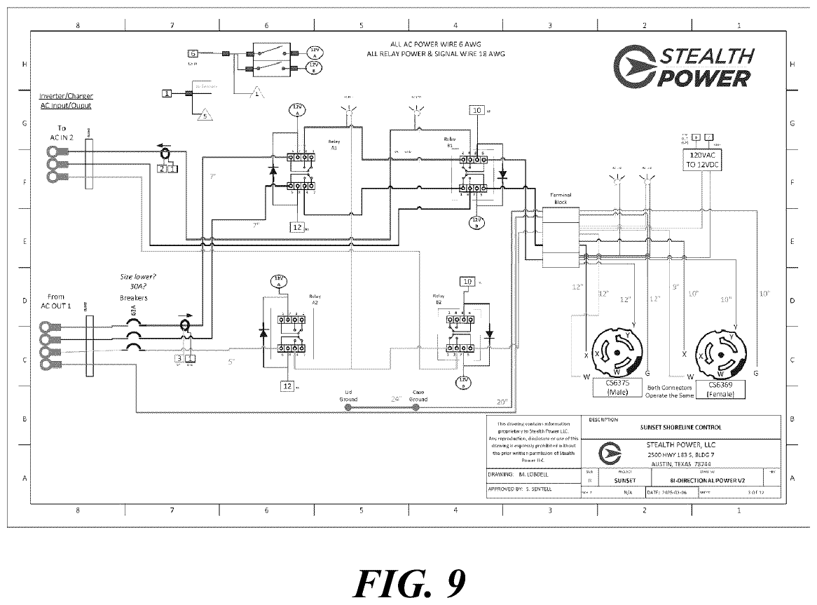

FIG. 9 depicts an electrical schematic view of the same bi-directional power module (800). The figure illustrates line and neutral conductors (830) entering from the Stealth Grid In/Out connector (810), traversing through a terminal block (832), and then being selectively switched by multiple relays (804) arranged in A-side and B-side pairs (804A, 804B). One side of the relay set is coupled toward the inverter output and load bus (814), while the other side is coupled toward the inverter input or AC charging input (816). The schematic further shows a low-voltage power supply (834) converting an AC control feed (836) into a stabilized DC rail (838) used to energize relay coils (840) and to power status indicators (842). The drawing includes current-sensing elements, such as a current transformer or VA sensor (844) disposed around one or more conductors, which provide real-time measurements of power flow through the module (800). These sensor outputs are routed to a control interface (846) that, in the larger system, is coupled to a processor or microcontroller (900) executing the fleet-control logic described elsewhere in this disclosure.

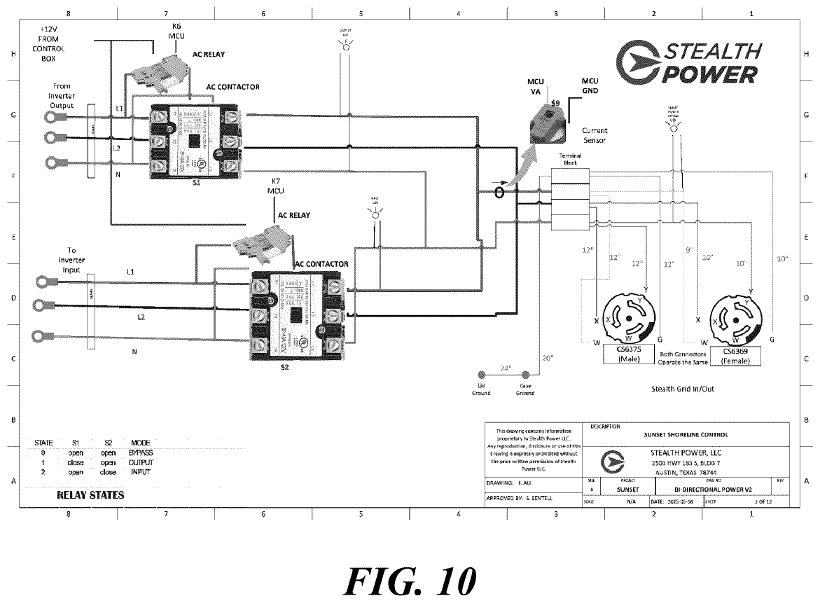

FIG. 10 presents a simplified functional diagram of a two-relay embodiment (850) of the bi-directional power module. In this configuration, a first relay (852) selectively connects the Stealth Grid In/Out connector (810) to the inverter output path (814), and a second relay (854) selectively connects the same connector (810) to the inverter input path (816). The diagram identifies a “From Output Inverter” node (814) on one side of the module and a “To Inverter Input” node (816) on the other side, with the Stealth Grid In/Out connector (810) forming a bidirectional junction that may act as an external AC source or sink for the modular power platform. Control lines (856) from the microcontroller (900) are shown driving the relay coils (852a, 854a) through low-voltage control terminals (858), while the current sensor (844) monitors the net flow through the Stealth Grid path. By energizing either the first relay (852), the second relay (854), or neither relay, the module can be placed into distinct operating modes that correspond to charging from an external source, exporting power to an external sink, or placing the module in a bypass or isolated condition.

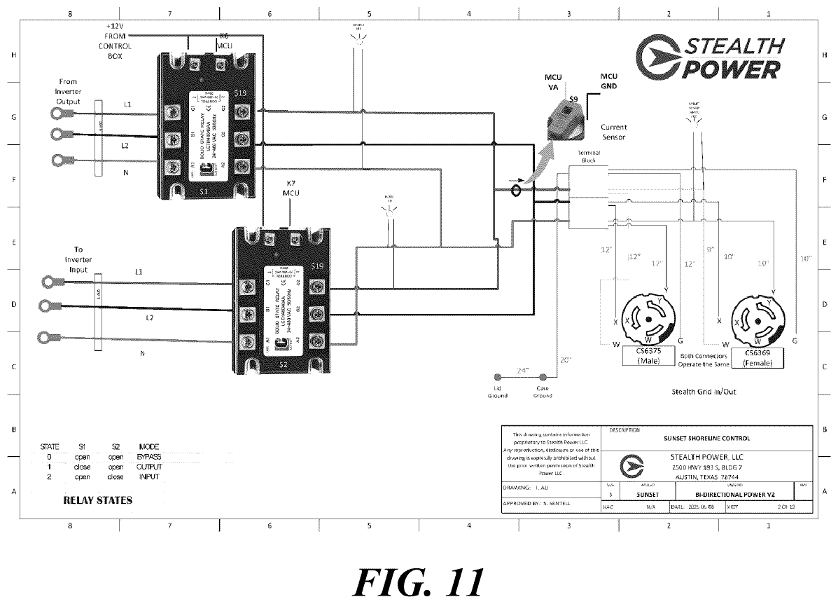

FIG. 11 further elaborates the control-plane integration between the bi-directional power module (800) and a smart charging control box or fleet controller (900). The drawing illustrates a microcontroller unit (MCU) (900) that receives the current sensor signal (844), line-voltage presence information (860), and additional diagnostic inputs (862) from the module. The MCU (900) provides a set of digital control outputs (864) that drive the relay coils (840) via driver circuitry (866) and may also drive status indicators such as LEDs (842) corresponding to Input, Output, and Smart modes. A low-voltage power connection (868) from the control box supplies the internal DC supply (838) of the module, establishing a clear segregation between the high-voltage AC domain (830) and the low-voltage control domain (868). This figure demonstrates how a control algorithm that predicts energy-storage conditions and computes allocation plans can, in practice, assert discrete relay states on the bi-directional module (800) using simple digital control signals, with continuous feedback from the current sensor (844) closing the loop.

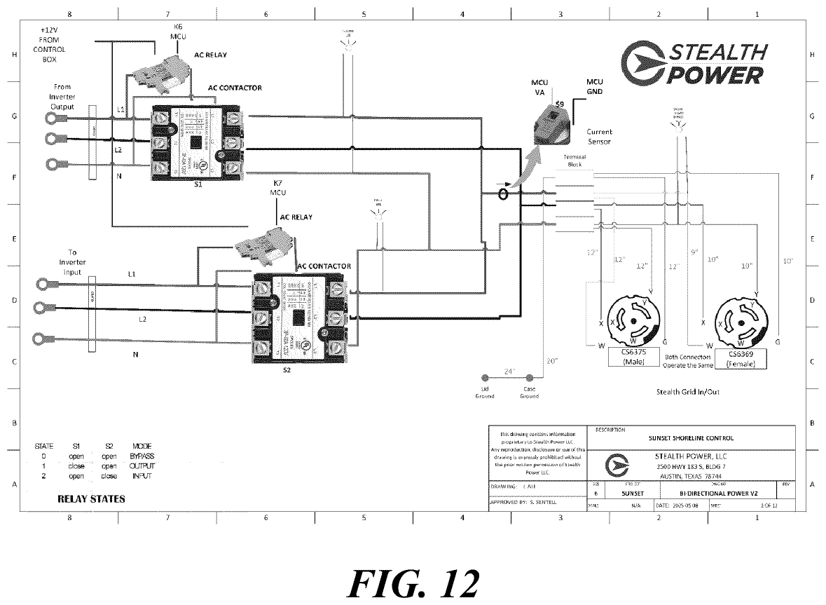

FIG. 12 illustrates an exemplary state definition table (870) for the two-relay embodiment (850) of the bi-directional module. In one representative implementation, the first relay (852) and the second relay (854) are each represented as either open or closed, and the combination of their states defines three distinct modes of operation. When the first relay (852) is closed and the second relay (854) is open, the module is in an output mode (872) in which power is exported from the inverter side (814) of the modular power platform to the Stealth Grid In/Out connector (810) for delivery to an external load, another modular power platform, or a local grid segment. When the first relay (852) is open and the second relay (854) is closed, the module is in an input mode (874) in which power from the Stealth Grid In/Out connector (810) is admitted toward the inverter input (816) for charging the onboard energy storage system or supplying local loads. When both relays (852, 854) are open, the module is in a bypass or isolated mode (876) in which there is no conductive path between the Stealth Grid connector (810) and the inverter paths (814, 816), thereby providing a safe state for maintenance, fault conditions, or periods in which external power exchange is not desired. The figure associates each combination of relay states with a symbolic state code (878) and a human-readable mode label (880), enabling the control firmware to implement a simple state machine that transitions between input, output, and bypass modes according to higher-level charging and orchestration policies.

Collectively, FIGS. 8-12 provide a detailed hardware realization of the external power interface and power-distribution interface described elsewhere in the specification. They show how a compact, mechanically packaged module with defined connectors (810, 812), high-current relays (804, 852, 854), and measurement components (844) can be integrated into the power system of a modular power platform and controlled by a smart charging control box or fleet controller (900). The figures also furnish concrete examples of relay topologies, current-sensing arrangements, and control-state definitions that permit the system to operate in a controlled and deterministic manner when switching between absorbing power from an external source and exporting power back toward that source or to other modular power platforms. These embodiments demonstrate how predictive control algorithms, policy snapshots, and deterministic allocation plans described in software-oriented sections of this disclosure can be implemented at the hardware level to provide a robust, deployable bi-directional power interface (800) for renewable-powered modular platforms.

Various programming languages and software libraries may be utilized to implement the foregoing system. In particular, the control algorithm software may be implemented using a suitable high-level programming language such as Python, C++, or Java, depending on the hardware platform and computational requirements. For microcontroller-based systems, Embedded C or C++ may be utilized. The software may run on a suitable microcontroller unit (MCU) such as, for example, an ARM Cortex-M series or ESP32, or on a single-board computer (SBC) such as the Raspberry Pi, which provides the necessary processing power, memory, and input/output interfaces.

The software requires sufficient memory to store historical data for predictive modeling. Non-volatile storage (such as an SD card or onboard flash memory) is used to retain data across power cycles. Data processing for predictive models may be offloaded to cloud-based services or edge computing devices if the local hardware resources are limited.

The software must interface with various sensors (such as, for example, for current, voltage, or SOC) and relays via communication protocols such as, for example, I2C, SPI, or UART. Accurate timing and synchronization are crucial to ensure system responses are real-time and reliable.

The control algorithm software for a solar-powered trailer may rely on several key hardware resources to function effectively. A microcontroller or microprocessor is at the core of the system, providing the computational power needed to run the control algorithm and handle various inputs and outputs. It processes data from sensors and manages communication with other hardware components to ensure optimal energy management.

Sensors play an important role by providing real-time data essential for monitoring and decision-making. These include AC current sensors to measure the power drawn from the shoreline, voltage sensors to monitor battery levels, and environmental sensors to assess conditions such as temperature and sunlight intensity. The data from these sensors are used by the control algorithm to predict energy needs and manage power flow efficiently.

The system also includes relays, such as an AC relay and a control relay, which physically execute the switching actions needed to control shoreline power input. These relays respond to control signals generated by the software, enabling or disabling power flow based on the algorithm's decisions.

To facilitate user interaction and provide feedback, the control box is equipped with user interface components. These may include buttons for manual overrides, LEDs to indicate operational status, or touchscreen displays that allow users to monitor system performance and adjust settings as needed. Together, these hardware resources enable the seamless integration of software and hardware, ensuring a reliable and efficient smart charging system.

Various types of batteries or battery arrays may be utilized to store and manage electrical energy generated by solar panels in the systems and methodologies described herein. These include, without limitation, traditional lead-acid batteries, such as Flooded Lead-Acid (FLA) and Sealed Lead-Acid (SLA) types such as Absorbent Glass Mat (AGM) and Gel batteries; lithium-ion batteries, including Lithium Iron Phosphate (LiFePO4), Lithium Nickel Manganese Cobalt Oxide (NMC), and Lithium Titanate (LTO); nickel-based batteries such as Nickel-Metal Hydride (NiMH) and Nickel-Cadmium (NiCd); sodium-ion, solid-state, and flow batteries; and hybrid battery arrays, which may combine different chemistries or integrate supercapacitors. The choice of battery for a particular implementation or application depends on considerations such as, for example, cost, energy density, cycle life, weight, temperature tolerance, safety, and maintenance. Advanced battery management systems and predictive algorithms may be utilized to further enhance efficiency and reliability in various operating conditions.

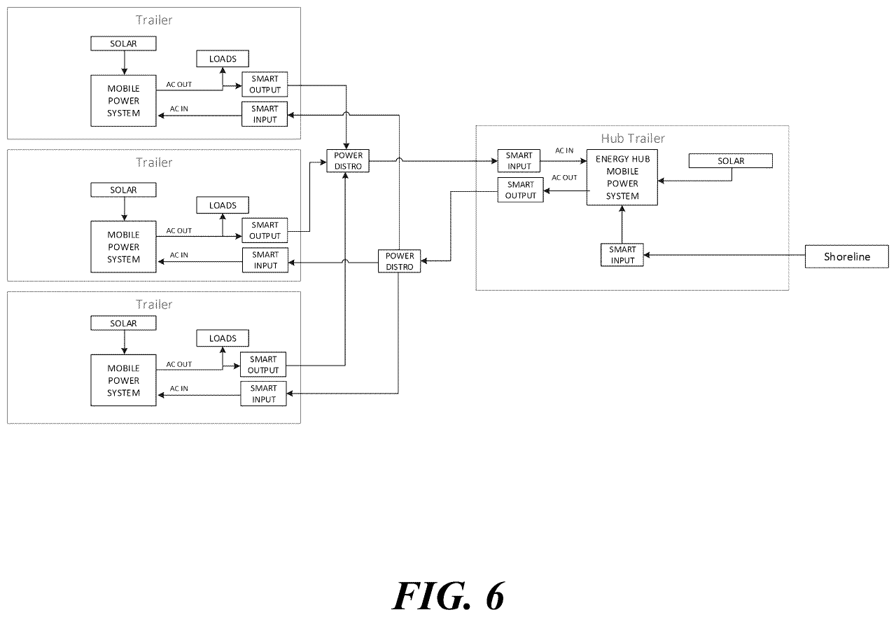

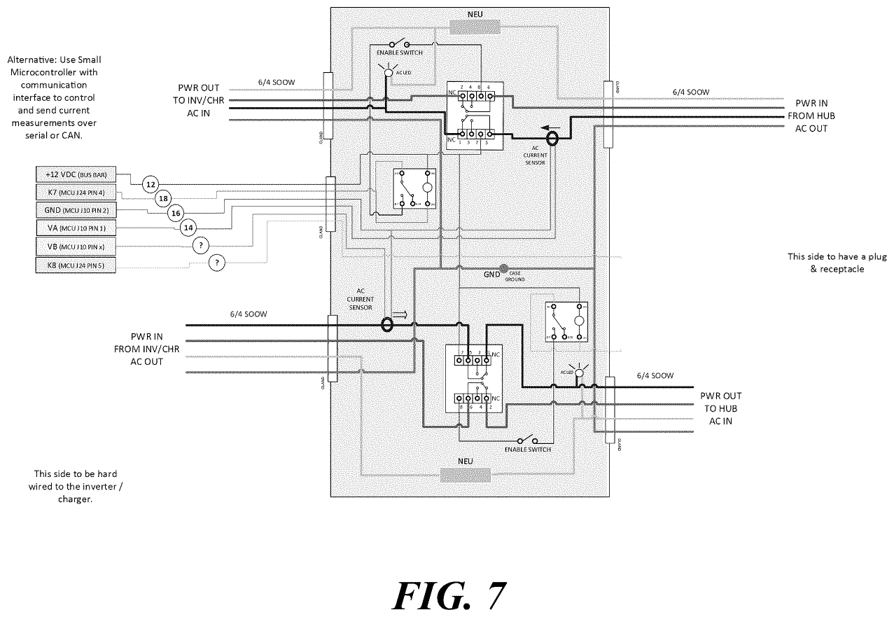

In some embodiments, the systems and methodologies disclosed herein are designed to optimize power distribution not only within the trailer they are installed in but also across multiple connected trailers. Such an embodiment is depicted in FIGS. 6-7. These systems may be equipped with a smart shoreline charger that allows power to flow into the trailer if its battery level is low (or is predicted to be low based on the control algorithm's forecasts). Additionally, an extra control box is integrated to manage power output, enabling the transfer of excess power to other trailers when the battery is sufficiently charged.

This dual-function capability ensures efficient power management, allowing one solar-powered trailer to serve as a central power hub that both receives and distributes power as needed. This configuration may be especially useful in environments such as large-scale events or emergency response operations, where multiple trailers require a reliable and scalable power source, thus enhancing resource utilization and reducing reliance on external power supplies.

In some embodiments of the systems and methodologies disclosed herein, the smart charging control box is equipped with integrated circuitry designed to manage bidirectional power flow. This capability enables the system not only to receive power from external sources, such as a shoreline or the solar panel array, but also to discharge power, supplying energy back to connected trailers or a local grid when the battery has excess capacity. This configuration allows the trailer to serve as both a power receiver and a power distributor, improving flexibility in multi-trailer arrangements and supporting grid-connected applications.

To optimize energy management across multiple connected trailers, the auxiliary control box may further include programmable logic controllers (PLCs). These controllers enable custom power distribution profiles tailored to the unique energy requirements of each trailer. In this way, the system can prioritize power to critical functions or applications, ensuring optimal use of available energy resources. The PLCs are programmable to respond dynamically to fluctuations in power demand or supply, enabling seamless power allocation.

In preferred embodiments of the systems and methodologies disclosed herein, the control algorithm may feature an anomaly detection module configured to identify unusual patterns in power usage or generation. This module uses historical and real-time data to detect deviations from expected performance, triggering preventive measures to avert system disruptions. For example, if the power output to a connected trailer suddenly spikes beyond typical consumption patterns, the anomaly detection module may alert the system and restrict output to prevent potential overloads or faults.

The learning component of the control algorithm preferably updates its predictive models based on discrepancies between predicted and actual battery behavior, thus improving accuracy over time. By continuously integrating feedback from real-world data, this component adapts its forecasting capabilities to changing conditions, battery aging, and variations in load patterns, ensuring more precise power management.

Additionally, some embodiments of the systems and methodologies disclosed herein are equipped with an auxiliary control box that integrates advanced circuit protection mechanisms. This box includes overcurrent and short-circuit protection features to secure power distribution across multiple trailers, thereby preventing damage to connected equipment and maintaining the integrity of the power network.

In some embodiments of the systems and methodologies disclosed herein, the solar panel array may be equipped with dual-axis tracking technology. This tracking system enables the array to adjust its orientation both horizontally and vertically in response to the sun's movement throughout the day. By aligning optimally with the sun's position, the dual-axis tracker maximizes solar energy capture, which may be particularly beneficial for off-grid scenarios where maximizing solar input is crucial for maintaining power autonomy.

In addition, some embodiments of the systems and methodologies disclosed herein may feature temperature and environmental sensors integrated within the smart charging control box. These sensors may allow the system to dynamically adjust the battery charging rate and overall power management based on ambient conditions. For example, on extremely hot days, the control algorithm may reduce the charging current to protect the battery from thermal degradation, thereby extending battery life and enhancing overall safety.

The systems, devices, and methodologies disclosed herein may be deployed with a wide range of renewable energy sources, either individually or in combination, serving as the first power source for a given modular power platform. In preferred embodiments, the first power source comprises one or more solar power subsystems, such as rooftop or ground-mounted photovoltaic arrays using monocrystalline, polycrystalline, or thin-film modules, which convert incident solar radiation into electrical energy suitable for charging the energy storage system. Other embodiments may employ wind power systems, including small-scale horizontal-axis or vertical-axis wind turbines mounted on or near the modular power platform, which can provide energy in conditions where solar generation is reduced, such as at night or during overcast periods. Still further embodiments may utilize geothermal power systems, such as ground-source heat pump arrangements or low-temperature geothermal generation modules, capable of extracting thermal energy from the subsurface environment and converting it into electrical power or offsetting other electrical loads.

Additional renewable or low-carbon sources may also be used to implement the first power source. For example, certain embodiments may integrate micro-hydroelectric generators in locations with flowing water, hydrokinetic or tidal devices in marine environments, or biomass-derived generation equipment, such as biogas or syngas gensets fueled by agricultural or municipal waste streams. In other implementations, waste-heat recovery systems or fuel cells may be coupled to the modular power platform to provide supplemental renewable or low-carbon energy. The control logic described herein treats each such renewable subsystem as a contributor to the first power source, monitoring its output via appropriate sensors and incorporating its generation characteristics into load and generation forecasts. In all cases, the predictive power management framework may be configured to preferentially utilize energy from these renewable sources (subject to policy-declared operating limits and reserve thresholds) before drawing power from an external power network via the external power interface.

The above description of the present invention is illustrative and is not intended to be limiting. It will thus be appreciated that various additions, substitutions and modifications may be made to the above-described embodiments without departing from the scope of the present invention. Accordingly, the scope of the present invention should be construed in reference to the appended claims. It will also be appreciated that the various features set forth in the claims may be presented in various combinations and sub-combinations in future claims without departing from the scope of the invention. In particular, the present disclosure expressly contemplates any such combination or sub-combination that is not known to the prior art, as if such combinations or sub-combinations were expressly written out.

What is claimed is:

A1. A smart charging system for a modular power platform configured to supply electrical power at a point of use, the system comprising:
a first power source configured to supply electrical energy to the modular power platform, the first power source comprising at least one renewable energy device;
an energy storage system configured to store the electrical energy supplied by the first power source and characterized by a state of charge;
an external power interface configured to receive electrical power from a power network that is external to the modular power platform;
a smart charging control box operatively connected to the energy storage system and the external power interface; and
at least one processor and non-transitory memory associated with the smart charging control box and storing instructions which, when executed by the at least one processor, configure the smart charging control box to
(a) monitor a current state of charge of the energy storage system,
(b) predict future energy-storage conditions based at least on historical load information and energy-generation information for the first power source, and
(c) selectively allow or block power intake from the external power interface based on the predicted energy-storage conditions so as to preferentially utilize the first power source while maintaining the energy storage system within policy-declared operating limits.

A2. The smart charging system of claim A1, wherein the instructions, when executed, further configure the smart charging control box to predict a load profile for the next 24 hours based on a rolling average of daily loads from a previous week adjusted for weekday and weekend variations.

A3. The smart charging system of claim A1, wherein the instructions, when executed, further configure the smart charging control box to predict energy generation from the first power source for the next 24 hours using a predictive model that factors in at least location, day of the year, and expected weather conditions.

A4. The smart charging system of claim A1, wherein the policy-declared operating limits comprise a target state-of-charge band selected to increase utilization of the first power source, and wherein the instructions, when executed, further configure the smart charging control box to adjust use of the external power interface to keep the energy storage system within the target state-of-charge band.

A5. The smart charging system of claim A1, wherein the smart charging control box includes at least one electrically controllable switching element in the external power interface, and the instructions, when executed, further configure the smart charging control box to generate relay control signals that cause the switching element to connect or disconnect the external power interface in response to the predicted future energy-storage conditions.

A6. The smart charging system of claim A1, wherein the smart charging control box is configured to maintain an electrical connection to the external power interface and to manage power flow between the external power interface and the energy storage system automatically without manual switching by a user.

A7. The smart charging system of claim A1, further comprising a wireless communication module coupled to the smart charging control box and configured to transmit real-time operational data and receive remote control commands.

A8. The smart charging system of claim A1, further comprising an emergency override mechanism that allows manual intervention to bypass automated control of power intake from the external power interface under a set of predefined conditions.

A9. The smart charging system of claim A8, wherein the set of predefined conditions includes at least one of a critical low state of charge of the energy storage system and a detected system malfunction.

A10. The smart charging system of claim A1, wherein the instructions, when executed, further configure the smart charging control box to drive a user interface that allows customization of charging parameters and display of system status information including at least a health indication for the energy storage system and an indication of utilization of the first power source.

A11. The smart charging system of claim A1, wherein the first power source comprises a solar panel array, and wherein the solar panel array comprises photovoltaic cells of a type selected from the group consisting of monocrystalline silicon, polycrystalline silicon, and thin-film solar cells.

A12. The smart charging system of claim A1, wherein the energy storage system comprises at least one battery and the smart charging control box includes at least one temperature sensor, and the instructions, when executed, further configure the smart charging control box to adjust a charging rate based on sensed temperature to improve battery health and charging efficiency.

A13. The smart charging system of claim A1, wherein the first power source comprises a solar panel array and the energy storage system comprises at least one onboard battery, and wherein the system is configured to interface with a grid-tied power system and, when the energy storage system is fully charged and the external power interface is disabled, to feed excess power back to an electrical grid.

A14. The smart charging system of claim A1, wherein the energy storage system comprises at least one battery, and the instructions, when executed, further configure the smart charging control box to adjust a charging strategy based on predictive maintenance data for the battery so as to extend an operational life of the battery.

A15. The smart charging system of claim A1, wherein the policy-declared operating limits comprise a minimum state-of-charge threshold below which power intake from the external power interface is enabled and a surplus threshold above which power intake from the external power interface is blocked.

A16. The smart charging system of claim A1, wherein the instructions, when executed, further configure the smart charging control box to modify the policy-declared operating limits in response to at least one of user preferences, detected degradation of capacity of the energy storage system, and changes in expected availability of the first power source.

A17. The smart charging system of claim A1, wherein the first power source comprises at least one renewable energy device selected from the group consisting of a solar power system, a wind power system, and a geothermal power system.

A18. The smart charging system of claim A1, wherein the power network external to the modular power platform comprises a shoreline power connection to an electrical grid.

B1. A method of managing power intake for a modular power platform configured to supply electrical power at a point of use, the method comprising:
monitoring a state of charge of an energy storage system configured to store electrical energy supplied by a first power source, the first power source comprising at least one renewable energy device;
predicting future energy-storage conditions of the energy storage system based at least on historical load information and energy-generation information for the first power source; and
selectively enabling or disabling power intake from a power network external to the modular power platform via an external power interface based on the predicted energy-storage conditions so as to preferentially utilize the first power source while maintaining the energy storage system within policy-declared operating limits.

B2. The method of claim B1, wherein predicting the future energy-storage conditions includes using historical load data and energy-generation data for the first power source.

B3. The method of claim B1, wherein predicting the future energy-storage conditions includes incorporating variations in load based on a type of day, and wherein the type of day is selected from the group consisting of weekdays and weekends.

B4. The method of claim B1, wherein the policy-declared operating limits comprise a minimum state-of-charge threshold at which power intake from the power network via the external power interface is enabled and a surplus threshold above which power intake from the power network via the external power interface is disabled.

B5. The method of claim B1, further comprising dynamically adjusting a duration or duty cycle of power intake from the power network via the external power interface based on real-time updates to load and energy-generation predictions.

B6. The method of claim B1, wherein predicting the future energy-storage conditions further includes using real-time data analytics to adjust the prediction based on sudden changes in weather conditions or unexpected power-consumption spikes.

B7. The method of claim B1, further comprising providing an alert or notification to a user when a predicted state of charge of the energy storage system falls below a predefined threshold, indicating a need for manual intervention or additional power input.

B8. The method of claim B1, wherein predicting the future energy-storage conditions is adjusted dynamically based on power-consumption patterns of specific loads connected to the modular power platform.

B9. The method of claim B1, further comprising integrating a feedback loop in which outcomes of previous predictions are analyzed to refine future prediction models for energy generation by the first power source and load on the modular power platform.

B10. The method of claim B1, wherein selectively enabling or disabling power intake from the power network via the external power interface is based not only on the predicted energy-storage conditions but also on availability and cost of power from the power network so as to optimize at least one of energy efficiency and cost savings.

B11. The method of claim B1, further comprising periodically calibrating sensors used for monitoring the state of charge of the energy storage system and energy input from the first power source to improve accuracy of the monitored data and the predicted energy-storage conditions.

C1. A power distribution system for a first modular power platform configured to supply electrical power at a point of use in conjunction with at least one additional modular power platform, the system comprising:
a first power source configured to generate electrical energy for the first modular power platform, the first power source comprising at least one renewable energy device;
an energy storage system on the first modular power platform configured to store the electrical energy generated by the first power source, the energy storage system being characterized by a state of charge (SOC);
an external power interface configured to receive electrical power for the first modular power platform from a power network external to the first modular power platform;
a smart charging control box operatively connected to the energy storage system and the external power interface;
an auxiliary control box configured to transfer power from the energy storage system of the first modular power platform to at least one of the additional modular power platforms; and
at least one processor and non-transitory memory associated with at least one of the smart charging control box and the auxiliary control box and storing instructions which, when executed by the at least one processor, configure the power distribution system to
(a) monitor the SOC of the energy storage system,
(b) predict, over a forecast interval, future energy-storage conditions based at least in part on historical load information and energy-generation information for the first power source,
(c) enable power intake from the external power interface when the predicted energy-storage conditions indicate that the SOC will fall below a policy-declared input threshold,
(d) inhibit power intake from the external power interface when the predicted energy-storage conditions indicate that the SOC will remain above the policy-declared input threshold for the forecast interval, and
(e) enable power transfer from the energy storage system to the at least one of the additional modular power platforms when the predicted energy-storage conditions indicate that the SOC exceeds a policy-declared export threshold.

C2. The power distribution system of claim C1, wherein the policy-declared input threshold is lower than the policy-declared export threshold so that power transfer to the at least one additional modular power platform is enabled only when the energy storage system has a surplus above a reserve level.

C3. The power distribution system of claim C1, wherein the instructions, when executed, configure the power distribution system to predict the SOC of the energy storage system over the forecast interval based on historical load information and energy-generation information for the first power source.

C4. The power distribution system of claim C1, wherein the smart charging control box includes a relay or other electrically controllable switching element that selectively enables or disables power intake from the external power interface based on at least one of real-time and predicted energy-storage conditions.

C5. The power distribution system of claim C1, wherein the auxiliary control box is configured to automatically transfer power from the energy storage system to the at least one additional modular power platform when a predicted SOC of the energy storage system exceeds a predefined export threshold, thereby enabling efficient power sharing across multiple modular power platforms.

C6. The power distribution system of claim C1, further comprising a predictive control module implemented by the instructions, the predictive control module being configured to adjust power input from the external power interface and power output to the at least one additional modular power platform based on environmental conditions including solar-generation forecasts and anticipated power consumption of the modular power platforms.

C7. The power distribution system of claim C1, wherein the smart charging control box and the auxiliary control box are configured to communicate with each other to synchronize power intake from the external power interface and power export to the at least one additional modular power platform based on overall power requirements of the modular power platforms.

C8. The power distribution system of claim C1, wherein the first power source comprises a solar panel array that includes adjustable tilt mechanisms configured to automatically adjust an angle of the solar panel array throughout the day to increase solar energy capture based on a position of the sun.

C9. The power distribution system of claim C1, wherein the first power source comprises a solar panel array and further includes a dual-axis tracking system configured to continuously orient the solar panel array toward the sun.

C10. The power distribution system of claim C1, wherein the first power source comprises a solar panel array and the solar panel array comprises photovoltaic cells.

C11. The power distribution system of claim C1, wherein the first power source comprises a solar panel array that incorporates transparent photovoltaic glass configured to be integrated into windows of at least one modular power platform so as to expand a surface area available for solar energy collection without requiring additional physical space.

C12. The power distribution system of claim C1, wherein the first power source comprises a solar panel array connected to an energy-management subsystem that uses predictive analytics to forecast weather conditions and adjusts energy-storage and usage strategies to increase utilization of solar energy.

C13. The power distribution system of claim C1, wherein the energy storage system comprises an onboard battery that is a high-capacity lithium-ion battery.

C14. The power distribution system of claim C1, further including a battery-management system configured to monitor the state of charge and actively balance cell voltages across a battery pack forming at least part of the energy storage system.

C15. The power distribution system of claim C1, wherein the energy storage system includes thermal-management components configured to maintain the energy storage system, including the onboard battery, within a target operating temperature range under varying environmental conditions.

C16. The power distribution system of claim C1, further including a battery health-monitoring module configured to use diagnostic algorithms to predict battery degradation or failure and to recommend maintenance or replacement to reduce a likelihood of unexpected power outages.

C17. The power distribution system of claim C1, wherein the energy storage system comprises a hybrid storage system that combines a plurality of energy-storage technologies to provide both rapid energy release and high-capacity storage.

C18. The power distribution system of claim C1, wherein the smart charging control box includes a fail-safe mechanism that automatically switches to power intake from the external power interface in response to detection of a system error or malfunction in at least one of the first power source and a battery-management system, thereby helping to ensure continuous power supply.

C19. The power distribution system of claim C1, further including a dynamic load-management feature implemented by the smart charging control box, the dynamic load-management feature being configured to redistribute power between the external power interface and the energy storage system based on real-time power-consumption rates of loads connected to the first modular power platform.

C20. The power distribution system of claim C1, wherein the instructions, when executed, implement an artificial-intelligence-based module configured to predict future low states of charge of the energy storage system before they occur and to proactively manage power intake from the external power interface and power from the first power source to reduce occurrence of such low states of charge.

C21. The power distribution system of claim C1, further including a user interface coupled to the smart charging control box and configured to display analytics on power-input sources and a status of the energy storage system and to allow a user to manually override automatic settings for tailored energy management.

C22. The power distribution system of claim C1, wherein the smart charging control box is configured to receive firmware updates remotely to modify predictive algorithms and adapt to new energy-management practices.

C23. The power distribution system of claim C1, wherein the auxiliary control box includes one or more programmable logic controllers configured to implement custom power-distribution profiles for respective additional modular power platforms based on specific energy requirements and usage patterns.

C24. The power distribution system of claim C1, further comprising a priority-setting feature in the auxiliary control box configured to prioritize distribution of power to critical systems in the additional modular power platforms during peak usage times or when overall system power is limited.

C25. The power distribution system of claim C1, wherein the auxiliary control box includes wireless communication circuitry configured to permit remote control and adjustment of power-output settings to the additional modular power platforms from a central monitoring location.

C26. The power distribution system of claim C1, further including an automatic synchronization feature in the auxiliary control box configured to synchronize power-output phases between the first modular power platform and the additional modular power platforms to help ensure stable power supply and reduce energy losses.

C27. The power distribution system of claim C1, wherein the auxiliary control box integrates circuit-protection components configured to protect against at least overcurrent and electrical faults in distribution of power to the additional modular power platforms.

C28. The power distribution system of claim C1, wherein the instructions, when executed, implement a machine-learning model configured to refine predictions of energy-storage conditions based on ongoing data collection regarding at least a life cycle of the energy storage system, usage patterns, and environmental factors.

C29. The power distribution system of claim C1, further comprising a decision-support component implemented by the instructions and configured to assist in real-time switching between power sources based on at least one of cost and energy-efficiency criteria.

C30. The power distribution system of claim C1, wherein the instructions, when executed, are configured to perform multi-variable optimization to balance power needs of the first modular power platform with power needs of the additional modular power platforms, taking into account immediate energy availability and forecasted energy production.

C31. The power distribution system of claim C1, further including an anomaly-detection module implemented by the instructions, the anomaly-detection module being configured to identify unusual patterns in power usage or generation and to trigger preventive measures to reduce a likelihood of system disruptions.

C32. The power distribution system of claim C1, wherein the instructions, when executed, are configured to integrate data from an external electrical grid to adapt power-input and power-output strategies in response to grid demands, thereby enabling participation in at least one of demand-response and grid-stabilization programs.

C33. The power distribution system of claim C1, wherein each modular power platform is implemented as a trailer and the first power source for the first modular power platform comprises a solar panel array mounted to the trailer.

D1. A smart charging system for a first modular power platform that operates in conjunction with a set of additional modular power platforms, the system comprising:
a first power source configured to charge an energy storage system on the first modular power platform, the energy storage system being characterized by a state of charge (SOC);
a power-distribution interface configured to transfer power from the energy storage system to at least one of the set of additional modular power platforms; a smart charging control box operatively connected to the energy storage system and the power-distribution interface; and
at least one processor and non-transitory memory associated with the smart charging control box and storing instructions which, when executed by the at least one processor, configure the smart charging control box to
(a) monitor the SOC of the energy storage system,
(b) predict future energy-storage conditions based at least on historical load data and energy-generation data for the first power source, and
(c) selectively allow or block power transfer through the power-distribution interface to the at least one of the set of additional modular power platforms based on (i) the monitored SOC of the energy storage system and (ii) a predictive analysis of power needs for the first modular power platform and the set of additional modular power platforms.

D2. The smart charging system of claim D1, wherein the instructions, when executed, further configure the smart charging control box to allow power transfer through the power-distribution interface to the at least one of the set of additional modular power platforms only when a predicted SOC of the energy storage system exceeds a policy-declared reserve threshold.

D3. The smart charging system of claim D2, wherein the instructions, when executed, further configure the smart charging control box to allow power transfer to the at least one of the set of additional modular power platforms only when both (i) the predicted SOC exceeds a policy-declared export threshold greater than the policy-declared reserve threshold and (ii) predicted energy generation from the first power source indicates excess power is available.

D4. The smart charging system of claim D1, wherein the smart charging control box includes an additional control module that manages power outflow through the power-distribution interface to the at least one of the set of additional modular power platforms, the additional control module being activated when the instructions determine that excess power generation is present.

D5. The smart charging system of claim D1, further comprising an external power interface configured to receive power from a power network external to the modular power platforms, the external power interface being operatively connected to the smart charging control box and configured, under control of the instructions, to allow power intake from the power network when the SOC is low or predicted to be low and to manage power outflow to the set of additional modular power platforms when the SOC is at or above a policy-declared export threshold.

D6. The smart charging system of claim D1, wherein the instructions, when executed, dynamically adjust power-distribution priorities between maintaining charge of the energy storage system and supplying power to the set of additional modular power platforms based on real-time energy needs and generation forecasts.

D7. The smart charging system of claim D1, wherein the instructions, when executed, incorporate real-time weather data to improve predictions of energy generation from the first power source and to adjust power-distribution schedules to the set of additional modular power platforms.

D8. The smart charging system of claim D1, wherein the smart charging control box includes multiple power-output ports, each configurable to different power-output levels depending on respective power needs of individual additional modular power platforms.

D9. The smart charging system of claim D1, further comprising a telemetry module configured to communicate with a central monitoring station to provide updates on system performance and power-distribution adjustments in substantially real time.

D10. The smart charging system of claim D1, further comprising an energy-generation forecasting module, implemented by the instructions, configured to predict future energy generation by the first power source using predictive analytics and to influence when and how much power is distributed to the set of additional modular power platforms.

D11. The smart charging system of claim D1, wherein the instructions, when executed, automatically reduce power output to the set of additional modular power platforms during peak consumption periods to preserve charge in the energy storage system of the first modular power platform.

D12. The smart charging system of claim D1, wherein the first power source comprises a solar panel array including a maximum power point tracking (MPPT) subsystem configured to dynamically adjust an operating voltage of the solar panel array to increase power output based on environmental conditions and the SOC of the energy storage system.

D13. The smart charging system of claim D1, wherein the first power source comprises a solar panel array in a modular configuration that permits panels to be added or removed responsive to seasonal variations in solar availability and power needs.

D14. The smart charging system of claim D1, wherein the first power source comprises a solar panel array coupled with a solar-irradiance sensor configured to measure an intensity of solar radiation, and wherein data from the solar-irradiance sensor is used by the instructions to predict optimal charging times and to manage charging cycles of the energy storage system.

D15. The smart charging system of claim D1, wherein the first power source comprises a solar panel array installed with adjustable mounting that can change orientation based on a position of the sun, the adjustable mounting being automatically controlled by the instructions to increase exposure to sunlight throughout the day.

D16. The smart charging system of claim D1, further including an energy-storage management subsystem configured to use the SOC of the energy storage system to determine when to store energy in one or more secondary storage devices, including supercapacitors, to handle peak load demands without depleting the energy storage system.

D17. The smart charging system of claim D1, wherein the smart charging control box includes integrated circuitry designed to manage bidirectional power flow so as to allow charging of the energy storage system and discharging from the energy storage system to at least one of an electrical grid and the set of additional modular power platforms.

D18. The smart charging system of claim D1, further including a wireless communication interface in the smart charging control box configured to enable remote monitoring and control of charging and power-distribution operations via at least one of a smartphone application and a web-based platform.

D19. The smart charging system of claim D1, wherein the smart charging control box is equipped with diagnostic capabilities, implemented by the instructions, that continuously analyze health of the energy storage system and predict potential faults before they affect performance.

D20. The smart charging system of claim D1, wherein the instructions, when executed, use machine-learning algorithms to optimize charging schedules based on past charging cycles, weather forecasts, and predicted energy-usage patterns.

D21. The smart charging system of claim D1, further including an environmental sensing module in the smart charging control box configured to measure at least temperature and humidity, and wherein the instructions, when executed, adjust charging parameters based on environmental conditions to extend a life of the energy storage system and enhance safety.

D22. The smart charging system of claim D1, wherein the instructions, when executed, include an adaptive learning component configured to update predictive models based on discrepancies between predicted and actual behavior of the energy storage system so as to improve prediction accuracy over time.

D23. The smart charging system of claim D1, further including a decision-support component implemented by the instructions and configured to provide recommendations regarding power-distribution priorities based on real-time analysis of power demands from the set of additional modular power platforms and available energy resources.

D24. The smart charging system of claim D1, wherein the instructions, when executed, utilize geospatial data to optimize power distribution by taking into account a geographic location of the first modular power platform and its exposure to sunlight when the first power source comprises a solar power system.

D25. The smart charging system of claim D1, further including an optimization routine implemented by the instructions and configured to calculate power-distribution decisions among the set of additional modular power platforms to reduce total energy consumption while increasing utilization of energy from the first power source.

D26. The smart charging system of claim D1, wherein the instructions, when executed, are further configured to interface with a local utility grid so as to permit participation in demand-response programs by adjusting power transfer to the set of additional modular power platforms based on grid needs and electricity prices.

D27. The smart charging system of claim D1, wherein each modular power platform is implemented as a trailer and the first power source for the first modular power platform comprises a solar panel array mounted to the trailer.

E1. A method for managing power distribution in a modular power platform system equipped with an energy storage system, the method comprising:
monitoring a state of charge (SOC) of the energy storage system of a first modular power platform;
predicting, for a future time interval, an energy-storage condition of the energy storage system of the first modular power platform based at least on historical load data and energy-generation data for a first power source associated with the first modular power platform; and
selectively enabling power transfer from the energy storage system of the first modular power platform to one or more additional modular power platforms only when the predicted energy-storage condition indicates that the SOC will remain above a policy-declared reserve threshold for the future time interval.

E2. The method of claim E1, further comprising enabling power intake from a power network external to the modular power platforms via an external power interface of the first modular power platform when the predicted energy-storage condition indicates that the SOC will fall below the policy-declared reserve threshold, and managing power distribution to the one or more additional modular power platforms when the predicted energy-storage condition indicates that the SOC is at or above a policy-declared export threshold.

E3. The method of claim E1, wherein managing power distribution includes activating an additional control module within a smart charging control box of the first modular power platform to route export power to the one or more additional modular power platforms based on real-time assessments of energy generation and energy consumption.

E4. The method of claim E1, further comprising dynamically adjusting power-distribution priorities between maintaining the SOC of the energy storage system of the first modular power platform above the policy-declared reserve threshold and supplying export power to the one or more additional modular power platforms based on continuous assessments of energy needs and energy-generation rates.

E5. The method of claim E1, wherein the predicting includes utilizing a combination of machine-learning models and historical energy-usage patterns to forecast energy needs for the first modular power platform and the one or more additional modular power platforms.

E6. The method of claim E1, further comprising dynamically regulating an amount of power transferred to each of the one or more additional modular power platforms based on respective platform power-consumption histories and predicted future power needs.

E7. The method of claim E1, wherein the predicting includes using machine-learning algorithms to refine energy-demand forecasts based on patterns of energy generation from the first power source and consumption changes attributable to seasonal variations.

E8. The method of claim E1, further comprising operating a load-balancing module to distribute available export power among the one or more additional modular power platforms so as to improve system stability and reduce a risk of overloading the energy storage system of the first modular power platform.

E9. The method of claim E1, further comprising adjusting power-distribution schedules based on priority settings assigned to the one or more additional modular power platforms, such that modular power platforms associated with critical applications receive power preferentially.

E10. The method of claim E1, further comprising remotely updating control logic used to implement the predicting and selectively enabling steps to incorporate new energy-management strategies and to adapt to additional types of connected modular power platforms or energy-consuming devices.

E11. The method of claim E1, wherein monitoring the SOC of the energy storage system includes continuously measuring at least voltage and current associated with the energy storage system to provide real-time data on energy-storage health and remaining capacity.

E12. The method of claim E1, further comprising employing impedance spectroscopy as part of the monitoring to detect and predict degradation of the energy storage system before the degradation materially affects performance.

E13. The method of claim E1, further comprising using temperature sensors integrated with a storage-monitoring subsystem to adjust SOC calculations based on temperature fluctuations that affect efficiency of the energy storage system.

E14. The method of claim E1, wherein the storage-monitoring subsystem is configured to send alerts to a central control system when the SOC falls below a predetermined threshold indicating an urgent need for charging to help prevent damage to the energy storage system.

E15. The method of claim E1, further comprising calibrating the monitoring of the SOC based on historical data collected over time so as to improve accuracy of SOC predictions and adapt to aging characteristics of the energy storage system.

E16. The method of claim E1, wherein the predicting includes utilizing a neural-network model trained on historical energy-consumption data and energy-generation data for the first power source to increase accuracy of forecasts of future energy-storage conditions.

E17. The method of claim E1, further comprising incorporating weather-forecast data into a predictive model to adjust predictions for energy generation from the first power source based on expected sunlight availability and weather conditions.

E18. The method of claim E1, wherein the predicting further considers expected load changes due to scheduled events or operational cycles within the one or more additional modular power platforms.

E19. The method of claim E1, further comprising using a regression-analysis model that factors in time of year and historical usage patterns to identify charging times and durations that are expected to improve life and efficiency of the energy storage system.

E20. The method of claim E1, further comprising dynamically updating one or more predictive models based on real-time data feedback to continuously refine accuracy of forecasts of future energy-storage conditions.

E21. The method of claim E1, wherein selectively enabling power transfer from the energy storage system of the first modular power platform includes applying a priority algorithm that ranks the one or more additional modular power platforms based on criticality of their power needs and availability of energy from the first power source.

E22. The method of claim E1, further comprising automatically adjusting, by a power-distribution subsystem, an amount of power distributed to each of the one or more additional modular power platforms based on real-time assessments of each platform's energy-consumption pattern and current energy need.

E23. The method of claim E1, further comprising using a load-forecasting module that predicts power requirements of each of the one or more additional modular power platforms and adjusts power-distribution schedules to optimize energy usage across the modular power platform system.

E24. The method of claim E1, further comprising providing a user-configurable setting that allows an owner or operator of the first modular power platform to override automated power-distribution decisions to address unexpected power needs in at least one of the one or more additional modular power platforms.

E25. The method of claim E1, further comprising integrating a feedback loop in which actual power-usage data received from the one or more additional modular power platforms is compared to forecasted usage, and using discrepancies between the actual and forecasted usage to refine the predictive models employed in the predicting step.

E26. The method of claim E1, wherein each modular power platform is implemented as a trailer and the first power source for the first modular power platform comprises a solar panel array mounted to the trailer.

F1. A computer-implemented method of orchestrating power distribution among a fleet of modular power platforms, each modular power platform having a first power source, an energy storage system characterized by a state of charge (SOC), and an external power interface configured to exchange power with a power network external to the modular power platforms, the method comprising:
receiving, at a hub modular power platform, fleet telemetry including per-platform SOC and first-source generation data and a policy snapshot specifying a forecast horizon and per-platform constraints;
predicting, for the forecast horizon, per-platform energy trajectories from the fleet telemetry;
computing an allocation plan that minimizes expected energy intake from the power network via the external power interface of the hub modular power platform subject to per-platform reserve and export constraints;
enabling power intake from the power network via the external power interface at the hub modular power platform only when predicted reserves under the allocation plan fail to satisfy the constraints, and disabling the power intake otherwise;
exporting power from the hub modular power platform to one or more peer modular power platforms only when a predicted surplus above a reserve threshold is available; and
executing the allocation plan deterministically such that identical inputs and the policy snapshot produce the same ordered actuator commands across the fleet.

F2. The method of claim F1, wherein the policy snapshot is identified by a version identifier and a verifier of origin.

F3. The method of claim F1, further comprising canonicalizing the fleet telemetry and the policy snapshot to a declared time base and numeric quantization including rounding and missing-data interpolation rules.

F4. The method of claim F1, wherein computing the allocation plan includes applying deterministic tie-breakers according to a priority-class mapping and a fixed platform-identifier ordering.

F5. The method of claim F1, wherein executing the allocation plan applies hysteresis bands and minimum on/off intervals to prevent relay chatter.

F6. The method of claim F1, wherein re-issuing an already-satisfied actuator command produces no change in actuator state.

F7. The method of claim F1, further comprising ordering all actuator commands using a monotonic sequence value and generating an audit artifact including the sequence value and a plan digest comprising a cryptographic hash over canonicalized inputs, the policy snapshot, and the allocation plan.

F8. The method of claim F1, further comprising recording the audit artifact and final actuator states in a tamper-evident hash-chained append-only log.

F9. The method of claim F1, further comprising verifying safety predicates including at least islanding protection status, overcurrent or thermal limits, and contactor interlock status before issuing actuator commands.

F10. The method of claim F1, wherein upon detecting an anomaly selected from telemetry staleness beyond a policy window, infeasible constraints, or a failed safety predicate, exports are frozen and power intake from the power network via the external power interface at the hub modular power platform is enabled until restoration.

F11. The method of claim F1, wherein the reserve constraint is SOC(i)≥S_min(i) and the export constraint is export(i)≤P_max(i) for each modular power platform i over the forecast horizon.

F12. The method of claim F1, further comprising assigning each modular power platform in the fleet to a priority class, and wherein computing the allocation plan includes allocating export power from the hub modular power platform so that modular power platforms assigned to higher priority classes are scheduled to receive power before modular power platforms assigned to lower priority classes when available export power is limited.

F13. The method of claim F1, wherein computing the allocation plan further comprises incorporating cost information associated with energy obtained from the power network and adjusting the allocation plan so as to trade off at least power-network energy cost against satisfaction of the per-platform reserve and export constraints.

F14. The method of claim F1, further comprising receiving grid-demand or demand-response signals from an external electrical grid and modifying the allocation plan to reduce power intake from the power network or export power from the hub modular power platform in accordance with the grid-demand or demand-response signals while maintaining the per-platform reserve constraints.

F15. The method of claim F1, further comprising incorporating geospatial data and weather-forecast data into the predicting step so that the per-platform energy trajectories reflect at least location-dependent energy availability from the first power source for respective modular power platforms in the fleet.

F16. The method of claim F1, wherein computing the allocation plan comprises using different forecast horizons for different objectives, including a first forecast horizon for reliability constraints that protect the per-platform reserve constraints and a second, longer forecast horizon for optimizing at least one of power-network energy cost and fleet-wide utilization of energy from the first power source.

F17. The method of claim F1, further comprising, in response to detecting that the hub modular power platform is unavailable or no longer able to act as a power source, selecting another modular power platform in the fleet as a replacement hub modular power platform and recomputing the allocation plan with the replacement hub modular power platform as a source of power intake from the power network and export power.

F18. The method of claim F1, further comprising transmitting the audit artifact generated in connection with execution of the allocation plan to a remote fleet-management service and storing the audit artifact at the remote fleet-management service for subsequent verification of compliance with the per-platform constraints and the policy snapshot.

F19. The method of claim F1, wherein the policy snapshot includes a digital signature or other verifier of origin, and further comprising verifying the policy snapshot before computing the allocation plan so that only authenticated policy snapshots are used for fleet-wide power-distribution decisions.

F20. The method of claim F1, wherein each modular power platform is implemented as a trailer and the first power source for at least the hub modular power platform comprises a solar panel array mounted to the trailer and the external power interface comprises a shoreline power connection.

G1. A fleet-orchestration system for coordinated power management among a plurality of modular power platforms, each modular power platform having a first power source, an energy storage system characterized by a state of charge (SOC), and an external power interface configured to exchange power with a power network external to the modular power platforms, the system comprising:
a hub modular power platform comprising at least one processor and non-transitory memory storing instructions which, when executed, cause the at least one processor to obtain fleet telemetric data including SOC values and first-source generation information for the plurality of modular power platforms and to access a policy snapshot specifying a forecast horizon and per-platform power-management constraints;
an external power interface on the hub modular power platform and including an electrically controllable actuator operable to enable or disable power intake from the power network to the hub modular power platform;
a power-distribution interface coupled to the hub modular power platform and to a set of peer modular power platforms, the power-distribution interface including power-switching circuitry and measurement circuitry for transferring power between the hub modular power platform and the peer modular power platforms; and
a fleet-control module executed by the at least one processor and operatively coupled to the external power interface and the power-distribution interface, the fleet-control module being configured to
(i) generate, for the forecast horizon, predicted energy trajectories for the plurality of modular power platforms based at least on the fleet telemetric data,
(ii) evaluate the policy snapshot to determine reserve constraints and export constraints for respective modular power platforms,
(iii) compute an allocation plan that manages power intake from the power network at the hub modular power platform and power export from the hub modular power platform to the peer modular power platforms in view of the predicted energy trajectories and the reserve and export constraints,
(iv) control the external power interface so that power intake from the power network at the hub modular power platform is enabled only when predicted behavior under the allocation plan would fail to satisfy at least one of the reserve constraints, and is disabled otherwise,
(v) control the power-distribution interface so that power is exported from the hub modular power platform to one or more peer modular power platforms only when a predicted surplus above at least one of the reserve constraints is available, and
(vi) execute the allocation plan in a deterministic manner such that identical fleet telemetric data and policy snapshot produce an identical ordered sequence of actuator commands for the external power interface and the power-distribution interface.

G2. The system of claim G1, wherein the power-distribution interface comprises an auxiliary control box including bidirectional power ports, contactors, current sensors, and a programmable logic controller (PLC).

G3. The system of claim G1, wherein the reserve constraints comprise, for each modular power platform i, a minimum SOC S_min(i) over the forecast horizon and the export constraints comprise, for each modular power platform i, a maximum outbound power P_max(i).

G4. The system of claim G1, wherein the fleet-control module is configured to compute the allocation plan so as to minimize expected energy intake from the power network or to prioritize fleet-wide utilization of energy from the first power source subject to the reserve and export constraints.

G5. The system of claim G1, wherein exporting power to a peer modular power platform is conditioned on a surplus margin ΔS(i) above S_min(i) meeting or exceeding a policy-declared surplus threshold.

G6. The system of claim G1, wherein the fleet-control module is configured to apply hysteresis bands and minimum on/off intervals when actuating the external power interface and the power-distribution interface so as to reduce relay chatter.

G7. The system of claim G1, wherein the fleet-control module is configured to schedule export power from the hub modular power platform according to a priority queue that classifies modular power platforms by declared priority classes and assigns higher priority to modular power platforms associated with critical loads.

G8. The system of claim G1, further comprising a determinism and audit subsystem configured to compute a time-based plan identifier comprising a monotonic sequence value and a plan digest over at least the allocation plan and the policy snapshot, such that identical fleet telemetric data and policy snapshot yield the same ordered sequence of actuator commands and the same plan identifier.

G9. The system of claim G8, wherein the plan digest comprises a cryptographic hash.

G10. The system of claim G1, wherein the policy snapshot is identified by a version identifier and a verifier of origin.

G11. The system of claim G1, wherein the fleet-control module is further configured, upon detecting that the hub modular power platform is unavailable, to select a different modular power platform in the plurality of modular power platforms as a replacement hub modular power platform and to recompute the allocation plan using the replacement hub modular power platform.

G12. The system of claim G1, wherein the fleet-control module is configured, when unable to satisfy the per-platform power-management constraints using energy from the first power source and export power alone, to increase power intake from the power network at the hub modular power platform as a fail-safe mode.

G13. The system of claim G1, further comprising a telemetry module configured to transmit fleet telemetric data and policy-snapshot identifiers to a remote monitoring or fleet-management service.

G14. The system of claim G1, wherein the fleet-control module is configured to receive demand-response or grid-event signals from an external electrical grid and to modify the allocation plan so as to adjust power intake from the power network and export power in accordance with the signals while maintaining the per-platform power-management constraints.

G15. The system of claim G1, wherein the fleet-control module is configured to incorporate geospatial data and weather-forecast data into the predicted energy trajectories so that forecasted availability of energy from the first power source for different modular power platforms is location dependent.

G16. The system of claim G8, wherein the time-based plan identifier further comprises a cryptographic hash computed over at least the policy snapshot and a canonical representation of the allocation plan.

G17. The system of claim G1, wherein the fleet-control module is configured to verify one or more safety predicates, including at least islanding protection status and overcurrent limits, before issuing actuator commands to the external power interface and the power-distribution interface, and to suppress actuator commands upon failure of at least one safety predicate.

G18. The system of claim G1, wherein the per-platform power-management constraints include, for each modular power platform i, the minimum SOC S_min(i) and the maximum export power limit P_max(i).

G19. The system of claim G1, wherein the fleet-control module is further configured to log violations or attempted violations of the per-platform power-management constraints in association with the time-based plan identifier for subsequent audit.

G20. The system of claim G1, wherein each modular power platform is implemented as a trailer and a first power source for at least the hub modular power platform comprises a solar panel array mounted to the trailer and the external power interface comprises a shoreline power connection to an electrical grid.
